(19) United States
(12) Patent Application Publication
(10) Pub. No.: US 2026/0258578 A1
(43) Pub. Date: Sep. 3, 2026

(54) SILICON INGOT, CRUCIBLE FOR SILICON INGOT PRODUCTION, METHOD FOR MANUFACTURING CRUCIBLE FOR SILICON INGOT PRODUCTION, AND METHOD FOR PRODUCING SILICON INGOT

(71) Applicant: Mitsubishi Materials Electronic Chemicals Co., Ltd., Akita-shi (JP)

(72) Inventors: Hidenori Suzuki, Akita-shi (JP); Koji Tsuzukihashi, Akita-shi (JP); Nozomi Konishi, Akita-shi (JP); Hiroyasu Ichikawa, Akita-shi (JP)

(73) Assignee: Mitsubishi Materials Electronic Chemicals Co., Ltd., Akita-shi (JP)

(21) Appl. No.: 19/148,336

(22) PCT Filed: Mar. 25, 2024
(86) PCT No.: PCT/JP2024/011635

§ 371 Date: Jul. 16, 2025

(30) Foreign Application Priority Data
Mar. 31, 2023 (JP) 2023-057654

(51) Int. Cl. C30B 11/00; B28B 1/16; C01B 33/02; C30B 29/06

(52) U.S. Cl. CPC C30B 11/002; C01B 33/02; C30B 29/06; B28B 1/16; C01P 2006/80

(57) ABSTRACT

This silicon ingot is consisting of a unidirectional solidification structure, in which a number density of heterogeneous inclusions having an equivalent circle diameter of 3 μm or more is less than 0.01 pieces/cm². In a crucible (20) for producing the silicon ingot, slurry layers (23) consisting of fine silica powder having an average particle diameter of 1 μm or more and 200 μm or less and colloidal silica and stucco layers (24) consisting of coarse silica powder having an average particle diameter of 100 μm or more and 1,000 μm or less are alternately laminated in a thickness direction on an inner surface of a mold (21). The innermost layer in contact with a silicon ingot is a slurry layer (23), and a total number of the slurry layers (23) and the stucco layers (24) is 6 or more.

### TECHNICAL FIELD

The present invention relates to a silicon ingot consisting of a unidirectional solidification structure, a crucible for silicon ingot production, a method for manufacturing a crucible for silicon ingot production, and a method for producing a silicon ingot.

Priority is claimed on Japanese Patent Application No. 2023-057654, filed Mar. 31, 2023, the content of which is incorporated herein by reference.

### BACKGROUND ART

In the related art, in various apparatus, for example, a plasma etching apparatus, a plasma CVD apparatus, and the like, which are used in a step of manufacturing a silicon semiconductor device, silicon members having the same material as the silicon wafer are widely used in order to suppress the occurrence of contamination in the apparatus. The above-described silicon members are manufactured from, for example, a silicon ingot consisting of a unidirectional solidification structure.

The silicon ingot having a unidirectional solidification structure is widely used as a material for parts that are used in semiconductor manufacturing apparatuses such as a sputtering apparatus for a liquid crystal, a plasma etching apparatus, and a CVD apparatus, as disclosed in, for example, Patent Document 1.

In addition, as disclosed in Patent Document 2, the suppression of abnormal discharge or generation of particles is considered to be a problem to be solved in a plasma treatment apparatus. An inclusion contained in the silicon member causes abnormal discharge in a case where the member is consumed and the inclusion is exposed to the surface during a dry etching process and causes particle generation when the member is further consumed and there is detachment from the member.

### CITATION LIST

### Patent Documents

[Patent Document 1] Japanese Patent No. 4531435
[Patent Document 2] Japanese Unexamined Patent Application, First Publication No. 2015-106652

### SUMMARY OF INVENTION

### Technical Problem

By the way, in producing a silicon ingot, there was a risk in that the silicon ingot would be cracked when the silicon ingot was taken out of the crucible after casting.

For this reason, in the related art, a mold releasing agent may be applied onto the inner wall of the crucible to peel off the silicon ingot from the crucible. In general, silicon nitride (silicon nitride film) is used as the mold releasing agent. Therefore, the nitrogen concentration in the ingot cannot be sufficiently reduced, and the contamination with heterogeneous inclusions such as silicon nitride cannot be avoided. In addition, when a carbon member was arranged in the inside of the manufacturing apparatus, there was a risk in that the silicon ingot would be contaminated with a heterogeneous inclusion such as silicon carbide.

The present invention has been made in consideration of the above-described circumstances, and an object of the present invention is to provide a silicon ingot in which the contamination with heterogeneous inclusions is sufficiently suppressed, a crucible for silicon ingot production that is used in producing a silicon ingot, a method for manufacturing a crucible for silicon ingot production, and a method for producing a silicon ingot.

### Solution to Problem

As a result of diligent studies by the inventors of the present invention in order to solve the above-described problems, it was found that the silicon ingot can be taken out satisfactorily without using a mold releasing agent such as silicon nitride and the contamination with inclusions can be sufficiently suppressed by making a crucible (a crucible for silicon ingot production) used in producing a silicon ingot into a specific structure.

The present invention has been made based on the above-described findings, and a silicon ingot according to an aspect 1 of the present invention is characterized by consisting of a unidirectional solidification structure, where a number density of heterogeneous inclusions having an equivalent circle diameter of 3 μm or more is less than 0.01 pieces/cm². The equivalent circle diameter is a diameter of a circle having an area equal to a projection area of particles of heterogeneous inclusions and can be measured by observing the cross section of the silicon ingot with an optical microscope or the like which is equipped with a micrometer. The equivalent circle diameter and the number density of the particles of heterogeneous inclusions may be measured by subjecting an optical photomicrographic image to image processing with a computer. The heterogeneous inclusions are those in which substances other than silicon, which contaminate a silicon ingot, are formed in a particle shape, and although not being limited, they mainly consist of silicon nitride or silicon carbide.

According to the silicon ingot according to the aspect 1 of the present invention, since the number density of heterogeneous inclusions having an equivalent circle diameter of 3 μm or more is set to be less than 0.01 pieces/cm², the contamination with heterogeneous inclusions is suppressed, and this silicon ingot is particularly suitable as a material of the silicon member capable of suppressing contamination, abnormal discharge, and particle generation. The number density of heterogeneous inclusions is measured by carrying out an observation of a cross section of the silicon ingot. Although the number density of heterogeneous inclusions having an equivalent circle diameter of 3 μm or more is not limited, it is more preferably less than 0.001 pieces/cm². The lower limit of the number density is not limited; however, considering the technical effect and the manufacturing cost, it may be set to about 0.0008 pieces/cm² from the industrial viewpoint.

A silicon ingot according to an aspect 2 of the present invention is characterized in that the nitrogen concentration is less than 1.0×10¹⁴ atoms/cc (atoms/cm³) in the silicon ingot according to the aspect 1 of the present invention.

According to the silicon ingot according to the aspect 2 of the present invention, since the nitrogen concentration is limited to less than 1.0×10¹⁴ atoms/cc, the contamination with heterogeneous inclusions such as silicon nitride is suppressed, and this silicon ingot is particularly suitable as a material of the silicon member capable of suppressing contamination, abnormal discharge, and particle generation. Although the nitrogen concentration is not limited, it is more preferably less than 5.0×10¹³ atoms/cc. The lower limit of the nitrogen concentration is not limited; however, considering the technical effect and the manufacturing cost, it may be set to about 1.0×10¹³ atoms/cc from the industrial viewpoint.

A silicon ingot according to an aspect 3 of the present invention is characterized in that the carbon concentration is less than 3.5×10¹⁷ atoms/cc in the silicon ingot according to the aspect 1 or the aspect 2 of the present invention.

According to the silicon ingot according to the aspect 3 of the present invention, since the carbon concentration is limited to less than 3.5×10¹⁷ atoms/cc, the contamination with heterogeneous inclusions such as silicon carbide is suppressed, and this silicon ingot is particularly suitable as a material of the silicon member capable of suppressing contamination, abnormal discharge, and particle generation. Although the carbon concentration is not limited, it is more preferably less than 2.0×10¹⁷ atoms/cc. The lower limit of the carbon concentration is not limited; however, considering the technical effect and the manufacturing cost, it may be set to about 1.0×10¹⁷ atoms/cc from the industrial viewpoint.

A crucible for silicon ingot production according to an aspect 4 of the present invention is a crucible for silicon ingot production that is used in producing a silicon ingot, in which slurry layers consisting of fine silica powder having an average particle diameter of 1 μm or more and 200 μm or less and colloidal silica and stucco layers consisting of coarse silica powder having an average particle diameter of 100 μm or more and 1,000 μm or less are alternately laminated in a thickness direction on an inner surface of a mold, where an innermost layer in contact with the silicon ingot is the slurry layer (23), and a total number of laminated layers of the slurry layers and the stucco layers is 6 or more. Although the shape of the crucible for silicon ingot production is not limited, it may be a bottomed tubular shape such as a bottomed cylindrical shape or a bottomed angular tube shape.

The average particle diameter in the present specification means a median diameter (D50) unless otherwise specified. The average particle diameter of the fine silica powder and the coarse silica powder is almost the same before and after deposition, and the average particle diameter can be measured even after the deposition. The slurry layer is a slurry layer obtained by applying or spraying a slurry, in which fine silica powder and colloidal silica are mixed, onto the inner surface of the mold or the inner surface of the stucco layer and then baking the slurry after drying, and the slurry layer has a structure in which the fine silica powder is bound while still having a particle shape. The colloidal silica is an aqueous dispersion liquid containing colloidal silica particles having a particle diameter of 100 nm or less at a high concentration. The stucco layer is a stucco layer obtained by spraying coarse silica powder onto the inner surface of the mold or the inner surface of the slurry layer and then baking the coarse silica powder, and the stucco layer has a porous structure in which the coarse silica powder is bound while still having a particle shape.

According to the crucible for silicon ingot production according to the aspect 4 of the present invention, slurry layers consisting of fine silica powder having an average particle diameter of 1 μm or more and 200 μm or less and colloidal silica and stucco layers consisting of coarse silica powder having an average particle diameter of 100 μm or more and 1,000 μm or less are alternately laminated in a thickness direction on an inner surface of a mold, where a total number of laminated layers of the slurry layers and the stucco layers is set to 6 or more, and thus the stress between a plurality of layers is alleviated when the silicon ingot is taken out, and the occurrence of cracking in the silicon ingot can be suppressed. In addition, since the innermost layer in contact with the silicon ingot is not composed of a mold releasing agent such as silicon nitride or silicon carbide, the generation of heterogeneous inclusions such as silicon nitride or silicon carbide can be suppressed during casting, which makes it possible to produce a silicon ingot in which these heterogeneous inclusions are sufficiently reduced.

The method for manufacturing a crucible for silicon ingot production according to an aspect 5 of the present invention is a method for manufacturing a crucible for silicon ingot production that is used in producing a silicon ingot, the method including slurry layer forming steps of applying or spraying a slurry consisting of fine silica powder having an average particle diameter of 1 μm or more and 200 μm or less and colloidal silica onto an inner surface of a mold to form a slurry layer, stucco layer forming steps of scattering coarse silica powder having an average particle size of 100 μm or more and 1,000 μm or less to form a stucco layer, and a baking step of baking laminated layers of the slurry layers and the stucco layers. The slurry layer forming steps and the stucco layer forming steps are each carried out three times or more and alternately repeated, a total number of the laminated layers of the slurry layers and the stucco layers is set to 6 or more, and then the baking step is carried out. The mixing ratio of the fine silica powder and the colloidal silica in the slurry is not limited; however, it is preferably 2:1 to 2:5 in terms of weight ratio. In addition, the content of colloidal silica particles in the colloidal silica is generally about 20% to 30% by mass.

According to a method for manufacturing a crucible for silicon ingot production according to an aspect 5 of the present invention, the method for manufacturing a crucible for silicon ingot production is configured such that slurry layer forming steps, stucco layer forming steps, and a baking step of baking the laminated slurry layer and the stucco layer are provided, and the slurry layer forming steps and the stucco layer forming steps are each carried out three times or more and alternately repeated, a total number of laminated layers of the slurry layers and the stucco layers is set to 6 or more, and then the baking step is carried out. Therefore, it is possible to manufacture a crucible for silicon ingot production in which silicon nitride or the like is not used in an innermost layer in contact with a silicon ingot, and a total number of the laminated slurry layers and the stucco layers is 6 or more.

A method for producing a silicon ingot according to an aspect 6 of the present invention is a method for producing a silicon ingot consisting of a unidirectional solidification structure, where the crucible for silicon ingot production described in the aspect 4 of the present invention is used. Specifically, the method includes a step of loading a silicon raw material into the crucible for silicon ingot production, a step of heating the crucible for silicon ingot production to melt the silicon raw material, and a step of producing a silicon ingot consisting of a unidirectional solidification structure by cooling the silicon melt from the lower part of the crucible for silicon ingot production.

According to the method for producing a silicon ingot according to the aspect 6 of the present invention, since the crucible for silicon ingot production described in the aspect 4 of the present invention is used, the stress applied to the silicon ingot can be reduced when the silicon ingot is taken out from the crucible, the occurrence of cracking in the silicon ingot can be suppressed, and since a mold releasing agent such as silicon nitride is not used, the generation of heterogeneous inclusions such as silicon nitride or silicon carbide in the silicon melt can be suppressed during casting, which makes it possible to produce a silicon ingot in which the number density of these heterogeneous inclusions is sufficiently reduced.

### Advantageous Effects of Invention

According to the present invention, it is possible to provide a silicon ingot in which the contamination of heterogeneous inclusions is sufficiently suppressed, a crucible for silicon ingot production which is used in producing the silicon ingot, a method for manufacturing a crucible for producing the silicon ingot, and a method for producing the silicon ingot.

### BRIEF DESCRIPTION OF DRAWINGS

FIG. 1 A longitudinal cross-sectional view showing an example of a silicon ingot production apparatus that is used in producing a silicon ingot, which is an embodiment according to the present invention.

FIG. 2 A longitudinal cross-sectional view of a crucible for silicon ingot production, which is an embodiment according to the present invention.

### DESCRIPTION OF EMBODIMENTS

Hereinafter, a silicon ingot which is an embodiment according to the present invention, a crucible for producing the silicon ingot, a method for manufacturing a crucible for producing the silicon ingot, and a method for producing the silicon ingot will be described with reference to the attached drawings. Each embodiment shown below is described specifically to allow the gist of the invention to be better understood and does not limit the present invention unless otherwise specified.

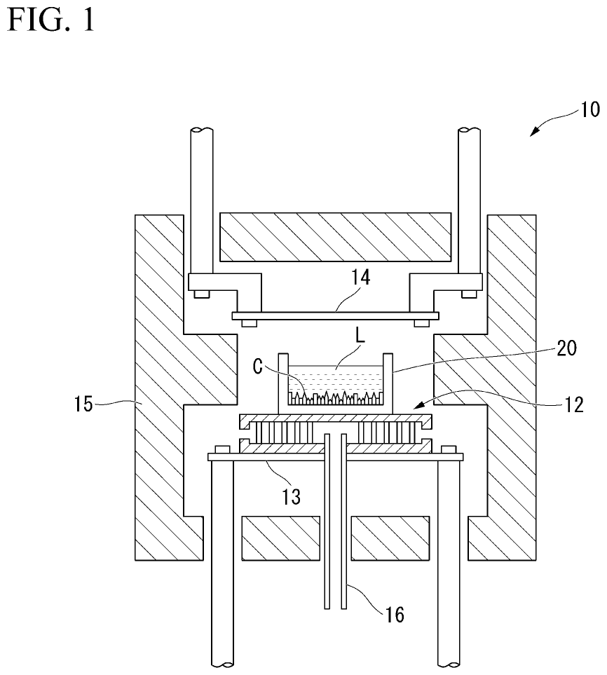

A silicon ingot, which is an embodiment according to the present invention, is produced, for example, by a silicon ingot production apparatus 10 shown in FIG. 1. The silicon ingot is a silicon ingot that is obtained by unidirectionally solidifying silicon melt upward from a bottom side of a crucible 20 in a crucible 20 for silicon ingot production, which is provided in a silicon ingot production apparatus 10, where the silicon ingot has a columnar crystal structure that extends vertically.

In the silicon ingot, which is the present embodiment, the number density of heterogeneous inclusions having an equivalent circle diameter of 3 μm or more is set to be less than 0.01 pieces/cm².

The number density of heterogeneous inclusions is checked by collecting an observation sample from a silicon ingot and observing the observation sample by mirror polishing. In the present embodiment, an observation sample was collected from an upper part of a unidirectionally solidified silicon ingot, and the number density of heterogeneous inclusions was measured with an optical microscope. The heterogeneous inclusions are those that contain silicon nitride and silicon carbide.

The number density of heterogeneous inclusions having an equivalent circle diameter of 3 μm or more is more preferable to be 0.001 pieces/cm² or less. The lower limit of the number density is not limited; however, considering the technical effect and the manufacturing cost, it may be set to about 0.0008 pieces/cm² from the industrial viewpoint.

In the silicon ingot, which is the present embodiment, the nitrogen concentration is preferably less than 1.0×10¹⁴ atoms/cc and more preferably less than 5.0×10¹³ atoms/cc. In the present embodiment, the nitrogen concentration of the silicon ingot is measured by secondary ion mass spectrometry (SIMS). The lower limit of the nitrogen concentration is not limited; however, considering the technical effect and the manufacturing cost, it may be set to about 1.0×10¹³ atoms/cc from the industrial viewpoint.

Further, in the silicon ingot which is the present embodiment, the carbon concentration is preferably less than 3.5×10¹⁷ atoms/cc and more preferably less than 2.0×10¹⁷ atoms/cc. In the present embodiment, the carbon concentration of the silicon ingot is measured by Fourier transform infrared spectroscopy (FT-IR). The lower limit of the carbon concentration is not limited; however, considering the technical effect and the manufacturing cost, it may be set to about 1.0×10¹⁷ atoms/cc from the industrial viewpoint.

Next, the silicon ingot production apparatus 10 that is used in producing a silicon ingot, which is the present embodiment, will be described with reference to FIG. 1.

The silicon ingot production apparatus 10 includes a bottomed cylindrical crucible for silicon ingot production, in which silicon melt L is stored; a chill plate 12 on which the crucible 20 for silicon ingot production is placed; an underfloor heater 13 that supports the chill plate 12 from the lower part and is allowed to be capable of carrying out ascending and descending operations; and a ceiling heater 14 that is arranged above the crucible 20 for silicon ingot production and allowed to be capable of carrying out ascending and descending operations. In addition, a heat insulating material 15 that forms a container shape openable/closable so that the periphery of the crucible 20 is surrounded is provided. The chill plate 12 is allowed to have a hollow structure and is configured such that Ar gas is supplied to the inside of the chill plate 12 through a supply pipe 16.

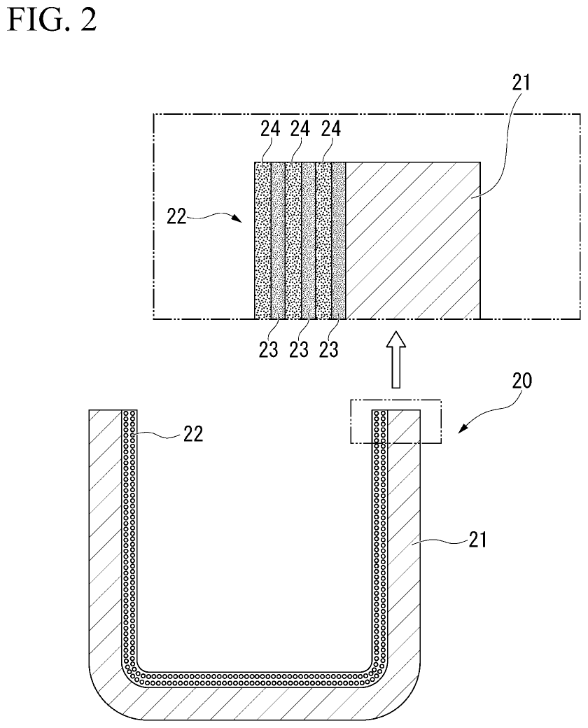

The crucible 20 for silicon ingot production, which is the present embodiment, will be described with reference to FIG. 2. The crucible 20 for silicon ingot production, which is the present embodiment, has a mold 21 and a silica layer 22 formed on the inner surface of the mold 21.

The mold 21 has a bottomed angular cylindrical shape (for example, a box shape with an open upper end), a bottomed cylindrical shape, or the like, and it is composed of, for example, quartz or graphite. A space having any dimension and shape (for example, a cylindrical space, a hexagonal columnar space, a cubic space, a rectangular parallelepiped space, or the like) is provided in the inside of the mold 21; however, it is not specifically limited. In the mold 21 in this example, the thickness of the bottom wall part and the thickness of the peripheral wall part are set to be approximately the same, and the inner peripheral surface and the outer circumferential surface are made to be a smooth curved surface at the boundary between the bottom wall part and the peripheral wall part; however, the thickness of the bottom wall part and the thickness of the peripheral wall part do not have to be the same, and both the inner circumferential surface and the outer circumferential surface may be intersected perpendicularly at the boundary.

As shown in FIG. 2, the silica layer 22 is provided in the inside of the mold 21 and is allowed to have a structure in which a slurry layer 23 consisting of fine silica powder having an average particle diameter of 1 μm or more and 200 μm or less and colloidal silica and a stucco layer 24 consisting of coarse silica powder having an average particle diameter of 100 μm or more and 1,000 μm or less are alternately laminated in a thickness direction, and an innermost layer in contact with the silicon ingot is allowed to serve as the slurry layer 23, and a total number of layers of the laminated slurry layers 23 and stucco layers 24 is set to 6 or more. The colloidal silica is an aqueous dispersion liquid containing colloidal silica particles having a particle diameter of 100 nm or less at a high concentration.

The slurry layer 23 is a slurry layer obtained by applying or spraying a slurry, in which fine silica powder and colloidal silica are mixed, onto the inner surface of the mold 21 or the inner surface of the stucco layer 24 and then baking the slurry after drying, and the slurry layer 23 has a structure in which the fine silica powder is bound while still having a particle shape. The colloidal silica is an aqueous dispersion liquid containing colloidal silica particles having a particle diameter of 100 nm or less at a high concentration, and it is in a slurry state in a case of being mixed with fine silica powder. The stucco layer 24 is a stucco layer obtained by spraying coarse silica powder onto the inner surface of the unbaked slurry layer 23 and then baking the coarse silica powder, and the stucco layer 24 has a porous structure in which the coarse silica powder is bound between the stucco layer 24 and the adjacent slurry layer 23 and is bound mutually while still having a particle shape.

In the present embodiment, the slurry layer 23 is formed at a place in contact with the inner surface of the mold 21 as shown in FIG. 2, and the total number of layers of the laminated slurry layers 23 and stucco layers 24 is set to 6.

In a case where the total number of layers of the laminated slurry layers 23 and stucco layers 24 is smaller than six layers, the stress when the silicon ingot is taken out cannot be alleviated completely, and the silicon ingot may be cracked. For this reason, in the present embodiment, the total number of layers of the laminated slurry layers 23 and stucco layers 24 is set to 6 layers or more. Although the upper limit of the total number of layers is not limited, the total number of layers may be industrially 10 layers or less due to the balance between the technical effect and the manufacturing cost.

In addition, by setting the average particle diameter of the fine silica powder within a range of 1 μm to 200 μm, the fine silica powder can be mixed with colloidal silica to form a slurry, which makes it possible to favorably form the slurry layer 23 described above. Further, by setting the average particle diameter of the coarse silica powder to 100 μm or more and 1,000 μm or less, the level of the surface roughness is not made higher than necessary, and peeling from the mold 21 is facilitated.

In addition, in the present embodiment, the thickness of the silica layer 22 (the total thickness of the laminated slurry layer 23 and stucco layer 24) is preferably 1 mm or more, and more preferably 2 mm or more. On the other hand, the thickness of the silica layer 22 (the total thickness of the laminated slurry layer 23 and stucco layer 24) is preferably 30 mm or less, and more preferably 25 mm or less.

Further, the thickness of the slurry layer 23 is preferably 0.1 mm or more and more preferably 0.2 mm or more. On the other hand, the thickness of the slurry layer 23 is preferably 5 mm or less, and more preferably 4 mm or less.

In addition, the thickness of the stucco layer 24 is preferably 0.1 mm or more and more preferably 0.2 mm or more. On the other hand, the thickness of the stucco layer 24 is preferably 5 mm or less, and more preferably 4 mm or less.

Next, a method for manufacturing the crucible 20 for silicon ingot production, which is the present embodiment, will be described.

A method for manufacturing a crucible 20 for silicon ingot production, which is the present embodiment, includes slurry layer forming steps of applying or spraying a slurry consisting of fine silica powder having an average particle diameter of 1 μm or more and 200 μm or less and colloidal silica onto an inner surface of a mold 21 to form a slurry layer 23; stucco layer forming step of scattering coarse silica powder having an average particle size of 100 μm or more and 1,000 μm or less to form a stucco layer 24; and a baking step of baking the laminated layers of slurry layers 23 and stucco layers 24. Although the mixing ratio of the fine silica powder and the colloidal silica in the slurry is not limited, it is preferably 2:1 to 2:5 in terms of weight ratio. In addition, the content of colloidal silica particles in the colloidal silica is generally about 20% to 30% by mass.

In addition, the configuration is such that the slurry layer forming step and the stucco layer forming step are each carried out three times or more and alternately repeated, the total number of layers of the slurry layers 23 and the stucco layers 24 is set to 6 or more, and then the baking step is carried out.

In the baking step, it is preferable that the conditions are set such that the atmosphere is an inert gas such as N₂ or Ar, the heating temperature is within a range of 800° C. to 1,200° C., and the holding time at the heating temperature is within a range of 1 hour to 10 hours.

Next, a method for producing a silicon ingot, which is the present embodiment using the silicon ingot production apparatus 10 shown in FIG. 1, will be described.

First, a silicon raw material is charged into the crucible 20 for silicon ingot, which is the present embodiment. As the silicon raw material, a lump-shaped raw material called “chunk” obtained by crushing high-purity silicon of 11 N (99.999999999) is used. For example, the particle diameter of the lump-shaped silicon raw material is set to 30 to 100 mm in terms of the dimension in the long-diameter direction.

The silicon raw material is heated by energizing the ceiling heater 14 and the underfloor heater 13. As a result, the heated silicon raw material is melted, and the silicon melt L is stored in the crucible 20 for producing the silicon ingot. As the condition after silicon dissolution, it is preferable to hold the heating temperature in a range of 1,420° C. or higher and 1,600° C. or lower in a period of time in a range of 5 hours or more 40 hours or less.

Next, the energization to the underfloor heater 13 is stopped, and Ar gas is supplied to the inside of the chill plate 12 through the supply pipe 16. As a result, the bottom part of the crucible 20 for silicon ingot production is cooled. Further, by gradually reducing the energization to the ceiling heater 14, the silicon melt L in the crucible 20 is cooled from the bottom part of the crucible 20 for silicon ingot production, and the columnar crystal C grows upward from the bottom part, thereby being solidified unidirectionally.

As for the casting condition, it is preferable to adjust the solidification rate to be within a range of 5 mm/h or more and 20 mm/h or less.

After the solidification is completed, the silicon ingot formed in the inside of the crucible 20 for silicon ingot production is taken out.

In this way, the silicon ingot, which is the present embodiment, is produced.

According to the silicon ingot which is the present embodiment that is configured as described above, since the number density of heterogeneous inclusions having an equivalent circle diameter of 3 μm or more is set to be less than 0.01 pieces/cm², the contamination with heterogeneous inclusions is sufficiently suppressed, and this silicon ingot is particularly suitable as a material of the silicon member capable of suppressing contamination, abnormal discharge, and particle generation.

In the silicon ingot which is the present embodiment, in a case where the nitrogen concentration is set to be less than 1.0×10¹⁴ atoms/cc, the contamination with heterogeneous inclusions containing nitrogen such as silicon nitride is suppressed, and this silicon ingot is particularly suitable as a material of the silicon member capable of suppressing contamination, abnormal discharge, and particle generation.

In the silicon ingot which is the present embodiment, in a case where the carbon concentration is set to be less than 3.5×10¹⁷ atoms/cc, the contamination with heterogeneous inclusions containing carbon such as silicon carbide is suppressed, and this silicon ingot is particularly suitable as a material of the silicon member capable of suppressing contamination, abnormal discharge, and particle generation.

According to the crucible 20 for silicon ingot production, which is the present embodiment, the slurry layer 23 consisting of fine silica powder having an average particle diameter of 1 μm or more and 200 μm or less and colloidal silica and the stucco layer 24 consisting of coarse silica powder having an average particle diameter of 100 μm or more and 1,000 μm or less are alternately laminated in a thickness direction on an inner surface of the mold 21, where a total number of layers of the laminated slurry layers 23 and stucco layers 24 is set to 6 or more, and thus the stress between a plurality of layers is alleviated when the silicon ingot is taken out, and the occurrence of cracking in the silicon ingot or the crucible 20 for silicon ingot production can be suppressed. In addition, since the innermost layer in contact with the silicon ingot is not composed of a mold releasing agent such as silicon nitride or silicon carbide, the generation of heterogeneous inclusions such as silicon nitride or silicon carbide can be suppressed during casting, which makes it possible to produce a silicon ingot in which these heterogeneous inclusions are sufficiently reduced.

According to the method for manufacturing the crucible 20 for silicon ingot production, which is the present embodiment, the method for manufacturing the crucible 20 for silicon ingot production is configured such that slurry layer forming steps, stucco layer forming steps, and a baking step of baking the laminated slurry layer 23 and stucco layer 24 are provided, and the slurry layer forming steps and the stucco layer forming steps are each carried out three times or more and alternately repeated, the total number of layers of the slurry layers 23 and the stucco layers 24 is set to 6 or more, and then the baking step is carried out. Therefore, it is possible to manufacture the crucible 20 for silicon ingot production in which the innermost layer in contact with the silicon ingot is allowed to serve as the slurry layer 23, and the total number of layers of the laminated slurry layers 23 and stucco layers 24 is 6 or more.

According to the method for producing a silicon ingot, which is the present embodiment, since the crucible 20 for silicon ingot production, which is the present embodiment, is used, the occurrence of cracking in the silicon ingot can be suppressed when the silicon ingot is taken out, and the generation of heterogeneous inclusions such as silicon nitride or silicon carbide can be suppressed during casting, which makes it possible to produce a silicon ingot in which these heterogeneous inclusions are sufficiently reduced.

As described above, one embodiment according to the present invention has been described. However, the present invention is not limited thereto and can be appropriately modified without departing from the technical idea of the invention.

In the present embodiment, the description has been made such that the total number of layers of the laminated slurry layers 23 and stucco layers 24 is set to 6 as shown in FIG. 2; however, the total number of layers is not limited thereto, and it may be 7 or more.

The outermost layer on the mold 21 side may be the slurry layer 23 or may be the stucco layer 24; however, it is preferably the slurry layer 23.

In addition, the innermost layer on the silicon melt L side may be the slurry layer 23 or may be the stucco layer 24; however, it is preferably the slurry layer 23.

### EXAMPLES

A confirmatory experiment carried out to confirm the effectiveness of the present invention is described.

### Example of Present Invention

A quartz mold with a bottomed cylindrical shape having dimensions of an inner diameter of 400 mm, an outer diameter of 450 mm, and a depth of 500 mm was prepared. Both the thickness of the side wall part and the thickness of the bottom wall part are 25 mm, and at the boundary between the side wall part and the bottom wall part, both the inner peripheral surface and the outer circumferential surface were made to be a curved surface.

Then, four times of the slurry layer forming step of applying a slurry obtained by mixing fine silica powder having an average particle diameter of 1 μm or more and 200 μm or less and colloidal silica at a ratio of 1:1 in terms of weight ratio to form a slurry layer, and three times of the stucco layer forming step of scattering coarse silica powder having an average particle size of 100 μm or more and 1,000 μm or less on the slurry layer before baking to form a stucco layer were carried out and alternately repeated, and the total number of layers of the slurry layers and the stucco layers was set to 7. After that, the baking step for the crucible was carried out under conditions of an atmosphere of N₂, a heating temperature of 800° C., and a holding time of 8 hours, and a crucible for producing the silicon ingot as an example of the present invention, in which a silica layer was formed on the inner surface of the mold, was manufactured. The total thickness of the slurry layer and the stucco layer (the thickness of the silica layer) was 3 mm.

A silicon raw material was loaded into the crucible for silicon ingot production as the example of the present invention, and thereafter, the temperature was held at 1,500° C., and the raw material was melted. A silicon melt obtained in the manner as described above was cooled at a cooling rate of 0.5° C./min from the lower part of the mold to produce a silicon ingot having a unidirectional solidification structure.

### Comparative Example

A quartz mold having dimensions of an inner diameter of 400 mm, an outer diameter of 450 mm, and a depth of 500 mm, which had the same shape and the same dimensions as the mold in Examples, was prepared.

In addition, a silicon nitride film having a thickness of 1 mm was formed as a mold release agent on the inner surface of the mold by a coating method to manufacture a crucible for silicon ingot production as a comparative example.

A silicon raw material was loaded into the crucible for silicon ingot production as the comparative example, and thereafter, the temperature was held at 1,500° C., and the raw material was melted. A silicon melt obtained in the manner as described above was cooled at a cooling rate of 0.5° C./min from the lower part of the mold to produce a silicon ingot having a unidirectional solidification structure.

Each measurement sample was collected at a position of a height of 15 mm from the upper surface of the obtained silicon ingot, and the number density, nitrogen concentration, and carbon concentration of heterogeneous inclusions having an equivalent circle diameter of 3 μm or more were measured.

For the number density of the heterogeneous inclusions, the number density of the heterogeneous inclusions having an equivalent circle diameter of 3 μm or more was calculated by subjecting the observation surface of the measurement sample to mirror polishing and visually observing the observation surface using a micrometer in an environment of a light intensity of 1,000 to 2,000 lx.

The nitrogen concentration was measured by secondary ion mass spectrometry (SIMS). The carbon concentration was measured by Fourier transform infrared spectroscopy (FT-IR).

For the calculation of the number density of heterogeneous inclusions, the measurement of nitrogen concentration, and the measurement of carbon concentration, each sample collected at the position at the same height in the same silicon ingot was used. The measurement results are shown in Table 1.

TABLE 1

| | | Silicon ingot | | |
|---|---|---|---|---|
| | Inner surface | | | Number density of |
| | structure of crucible | Nitrogen | Carbon | heterogeneous |
| | for silicon ingot | concentration | concentration | inclusions |
| | production | (atoms/cm³) | (atoms/cm³) | (pieces/cm²) |
| EXAMPLE | Silica layer | Less than 5.0 × | 1.9 × 10¹⁷ | Less than 0.0010 |
| | (laminated structure | 10¹³ | | |
| | of slurry layer and | | | |
| | stucco layer) | | | |
| COMPARATIVE | Silicon nitride film | 7.5 × 10¹⁶ | 8.5 × 10¹⁷ | 5.3 |
| EXAMPLE | | | | |

In the comparative example, a crucible for silicon ingot production in which a silicon nitride film was formed as a mold releasing agent on the inner surface of the mold was used, and thus the produced silicon ingot had a high nitrogen concentration and a high carbon concentration, the number density of heterogeneous inclusions was 5.3 pieces/cm², and a lot of heterogeneous inclusions were contained.

On the other hand, in the example of the present invention, a crucible for silicon ingot production in which the slurry layers and the stucco layers were alternately laminated on the inner surface of the mold, the innermost layer was allowed to serve as a slurry layer, and the total number of layers of the laminated slurry layers and stucco layers was set to 7 was used, and thus the produced silicon ingot had a sufficiently low nitrogen concentration and a high carbon concentration, the number density of heterogeneous inclusions was 0.001 pieces/cm², and there were almost no heterogeneous inclusions.

As described above, it has been confirmed that, according to the present invention, it is possible to provide a silicon ingot in which the contamination of heterogeneous inclusions is sufficiently suppressed, a crucible for silicon ingot production that is used in producing a silicon ingot, a method for manufacturing a crucible for silicon ingot production, and a method for producing a silicon ingot.

### INDUSTRIAL APPLICABILITY

According to the present invention, it is possible to provide a silicon ingot in which the contamination of heterogeneous inclusions is sufficiently suppressed, a crucible for silicon ingot production that is used in producing a silicon ingot, a method for manufacturing a crucible for silicon ingot production, and a method for producing a silicon ingot, and thus the present invention has industrial applicability.

### REFERENCE SIGNS LIST

20 Crucible for silicon ingot production
21 Mold
23 Slurry layer
24 Stucco layer

1. A silicon ingot consisting of a unidirectional solidification structure, in which a number density of heterogeneous inclusions having an equivalent circle diameter of 3 μm or more is less than 0.01 pieces/cm².

2. The silicon ingot according to claim 1, wherein a nitrogen concentration of the silicon ingot is less than 1.0×10¹⁴ atoms/cc.

3. The silicon ingot according to claim 1, wherein a carbon concentration of the silicon ingot is less than 3.5×10¹⁷ atoms/cc.

4. A crucible for silicon ingot production that is used in producing a silicon ingot, comprising:
a mold,
slurry layers consisting of fine silica powder having an average particle diameter of 1 μm or more and 200 μm or less and colloidal silica, and
stucco layers consisting of coarse silica powder having an average particle diameter of 100 μm or more and 1,000 μm or less,
wherein the slurry layers and the stucco layers are alternately laminated in a thickness direction on an inner surface of the mold, and a total number of laminated layers of the slurry layers and the stucco layers is 6 or more.

5. A method for manufacturing a crucible for silicon ingot production that is used in producing a silicon ingot, the method comprising:
slurry layer forming steps of applying or spraying a slurry containing fine silica powder having an average particle diameter of 1 μm or more and 200 μm or less and colloidal silica onto an inner surface of a mold to form slurry layers;
stucco layer forming steps of scattering coarse silica powder having an average particle size of 100 μm or more and 1,000 μm or less onto the inner surface of the mold to form stucco layers; and
a baking step of baking a laminated layers of the slurry layers and the stucco layers,
wherein the slurry layer forming steps and the stucco layer forming steps are each carried out three times or more and alternately repeated,
a total number of the laminated layers of the slurry layers and the stucco layers is set to 6 or more, and
the baking step is subsequently carried out.

6. A method for producing a silicon ingot comprising a unidirectional solidification structure,
wherein the method for producing a silicon ingot uses the crucible for silicon ingot production according to claim 4.
